(19) United States
(12) Patent Application Publication
(10) Pub. No.: US 2003/0172870 A1
(43) Pub. Date: Sep. 18, 2003

(54) Apparatus for growing monocrystalline group II-VI and III-V compounds

(75) Inventors: Xiao Gordon Liu, Fremont, CA (US); Weiguo Liu, Sunnyvale, CA (US)

Correspondence Address: SONNENSCHEIN NATH & ROSENTHAL, Sears Tower, Wacker Drive Station, P.O. BOX #061080, Chicago, IL, 60606-1080, US

(73) Assignee: AXT, Inc.

(21) Appl. No.: 10/097,844

(22) Filed: Mar. 14, 2002

(51) Int. Cl. C30B 35/00; C30B 1/00

(52) U.S. Cl. 117/200; 117/900

(57) ABSTRACT

An apparatus for producing large diameter monocrystalline Group III-V, II-VI compounds that have reduced crystal defect density, improved crystal growth yield, and improved bulk material characteristics. The apparatus comprises a crucible or boat, an ampoule that contains the crucible or boat, a heating unit disposed about the ampoule, and a liner disposed between the heating unit and the ampoule. The liner is preferably composed of a quartz material. When the liner and the ampoule are made of the same material, such as quartz, the thermal expansion coefficients of the liner and ampoule are the same, which significantly increases the lifetime of the liner and the single-crystal yield.

### FIELD

The invention relates to the growth of semiconductor crystals. More particularly, the invention relates to an apparatus for growing Group II-VI and III-V monocrystalline compounds.

### BACKGROUND

Electronic and opto-electronic device manufacturers routinely require commercially grown, large and uniform single semiconductor crystals. These crystals can be sliced and polished to provide substrates for microelectronic device production. An extensive range of deposition and lithography techniques well known in the art is employed to build thin film layers and microcircuits on the monocrystalline substrates to produce integrated circuits, light emitting diodes, semiconductor lasers, sensors, and other microelectronic devices. In radio-frequency integrated circuit and opto-electronic integrated circuit applications, crystalline uniformity and defect density are essential characteristics of the substrates that influence device production yield, life span, and performance. Consequently, improvements in crystal growth technology constitute an ongoing pursuit in academic and industrial research.

Compound semiconductor crystals are typically grown by one of four techniques: Liquid Encapsulated Czochralski (LEC), Horizontal Bridgman (HB), Horizontal Gradient Freeze (HGF), and Vertical Gradient Freeze (VGF). LEC is a commonly used technique for producing semi-insulating semiconductor crystals, such as GaAs. In the LEC process, a single crystal seed is lowered into a GaAs melt which is covered by a layer of boron oxide (B₂O₃) to prevent the loss of the volatile As and maintain stoichiometry. The temperature of the melt is reduced until crystallization starts on the seed. The seed is then raised at a uniform rate, and a crystal is pulled from the melt. The seed and melt are contained inside a steel chamber at high pressure to prevent the volatile Group V and Group VI elements of the polycrystalline compound from leaving the melt.

In the LEC process, because the cooling and crystallization occur above the heated melt, unstable convection in the melt and turbulence in the inert gas atmosphere in the growth system are inevitable. In addition, LEC requires a pronounced thermal gradient for success because it is necessary to cool a solidifying crystal rapidly to prevent the escape of volatile arsenic. As a consequence of this high gradient, crystals grown by LEC techniques tend to have a high intrinsic stress, and crystals grown under thermal stress are known to exhibit a relatively high defect density. The impact of this drawback is increasingly apparent in the growth of large diameter crystals. As used herein, “large diameter,” refers to crystals having a diameter on the order of several inches or greater. Large diameter crystals having exceptional substrate characteristics and uniformity are preferred by the electronics industry because such crystals significantly improve device production yield and reduce unit cost.

The horizontal crystal growth techniques, including Horizontal Bridgman and Horizontal Gradient Freeze, largely reduce the turbulence associated with LEC by using a horizontal furnace. In the horizontal growth techniques, crystals are grown in horizontal boats. The boat containing the raw materials is sealed in an ampoule. Heating elements are used to generate a temperature profile. After the polycrystalline compound melts, one of the temperature gradient, the ampoule, or the heater apparatus is slowly moved so that a solid-liquid interface moves along the length of the boat. Monocrystal growth results as the charge solidifies and cools.

Typically in horizontal techniques, growth is generally chosen to be in a <111> direction. The completed crystal has a cross-sectional shape matching the shape of the boat, most frequently a “D” shape. If the crystal is sawed perpendicular to its growth axis <111>, the resulting wafers are <111> material. However, usually (100) wafers are desired. For this reason, HB crystals are usually sawed at an angle of about 55° to the ingot axis. With this angular sawing, compositional variations along the axis of the crystal are translated into variations across individual wafers.

The HB technique does not scale well to large diameters as the technique produces non-cylindrical crystals. Wafers sliced from horizontally grown crystals must be ground to a circular shape for device manufacturing. Since silicon contamination is difficult to avoid in the horizontal growth technique, HB crystals are suitable for LED manufacturers but less attractive for electronics and high-performance opto-electronic device manufacturers.

The VGF technique for single crystal growth of compound semiconductors resembles the LEC technique in that the crystal is grown in a crucible in an apparatus with a high degree of vertical symmetry. Both VGF and LEC produce cylindrical crystals. The fundamental differences between LEC and VGF are the magnitude of the temperature gradient, the location of the seed crystal, and the direction of the crystal solidification. A VGF crystal growth system employs a smaller temperature gradient on the order of 10 degrees Celsius per centimeter or less, as compared with an LEC system in which the temperature gradient is typically 50-100 degrees Celsius per centimeter. Crystals grown in the relatively low temperature gradient of a VGF system incorporate less thermal stress and, consequently, are known to exhibit a lower defect density than those grown in LEC systems.

The seed crystal is positioned on the bottom of the crucible in a VGF system, and the crystal cools and solidifies from the bottom up. Contrasted with LEC, the VGF temperature gradient that controls the melting and cooling of the charge is inverted with the cooler crystal situated below the hotter melt. Thus, at the solid-liquid interface in an LEC process, turbulence can be a detrimental factor. VGF, with the crystal below the melt, does not suffer this problem.

VGF has been demonstrated to be highly scalable to the manufacture of large diameter single crystals. For this reason and because of the demonstrated high crystal quality, VGF is an appealing technology that produces crystals appropriate to consumer markets of compound semiconductor substrates, high-performance microelectronics and opto-electronics.

The productivity and crystal quality of VGF technology is improved by the inclusion of a ceramic or refractory diffuser between the quartz ampoule and the heating coils in the apparatus. A diffuser of mullite or silicon carbide is often inserted or installed in a VGF growth apparatus to reduce hot spots and turbulence. The diffuser provides more uniform heating and better temperature gradient control. As a result, crystals grown in an apparatus with a diffuser made of mullite or silicon carbide can be grown with reduced intrinsic stress.

Unfortunately, there are drawbacks associated with the use of mullite or silicon carbide diffusers in crystal growth apparatus when quartz ampoules are used. The diffusers become brittle after repeated cycles of heating and cooling. Also, the diffusers often break after a limited number of uses. An additional concern is the mismatch between the coefficients of thermal expansion of the diffuser and the ampoule. The crystal growth apparatus is often heated to temperatures in excess of 1,200 degrees Celsius. At these temperatures, the sealed quartz ampoule expands since the gas pressures inside and outside the ampoule are not balanced. During cooling, the ampoule tends to contract at a different rate than the furnace liner because quartz has a very low coefficient of thermal expansion. On the other hand, diffusers in the cooling phase tend to rapidly contract to their original dimensions. Diffusers made of mullite or silicon carbide compress the enlarged ampoule, often resulting in a break of the diffuser, ampoule or both. Ampoule breakage usually destroys the charge and thus severely reduces crystal production yield.

In practice, a silicon carbide diffuser can be used for 3 to 5 crystal growth cycles, making its benefit impracticably expensive. Mullite is less expensive, but the mullite is less useful as a diffuser because of relatively poor thermal conductivity compared to silicon carbide and the difficulty in obtaining high-quality large diameter mullite cylinders. Thus, mullite is of limited benefit in improving the uniformity of the temperature gradient.

### SUMMARY

Aspects of the present invention relate to an apparatus for producing monocrystalline Group III-V, II-VI compounds. The apparatus comprises a crucible or boat, an ampoule that contains the crucible or boat, and a heating unit disposed about the ampoule. A liner is disposed between the heating unit and the ampoule. The liner is preferably composed of a quartz material. When the liner and the ampoule are made of the same material, such as quartz, the thermal conductivities of the liner and ampoule are substantially the same, as are the thermal expansion coefficients of the liner and ampoule.

### BRIEF DESCRIPTION OF THE DRAWINGS

FIG. 1 shows an apparatus for growing monocrystalline Group II-VI and III-V compounds constructed according to a first embodiment of the invention; and

FIG. 2 shows an apparatus for growing monocrystalline Group II-VI and III-V compounds constructed according to a second embodiment of the invention.

### DETAILED DESCRIPTION

As used herein, the terms “quartz,” “fused quartz,” and “fused silica” are used interchangeably, and all refer to the entire group of materials made by fusing silica (SiO₂). Monocrystalline Group II-VI and III-V compounds having resistivities typically within the range of approximately 10⁻³ ohm-cm to 10⁹ ohm-cm are referred to as “semiconductors” (SC). Group II-VI and III-V monocrystalline compounds that have a resistivity greater than about 1×10⁷ ohm-cm are referred to as “semi-insulating” (SI) semiconductors. Depending on the doping level in Group II-VI and III-V compounds, the monocrystalline form may be “semi-insulating” in its “undoped” or intrinsic state, or in its “doped” state. Examples of compounds in doped states include GaAs with chromium or carbon as a dopant, and InP with iron as dopant. The terms “crucible” and “boat” are used interchangeably, as both refer to a container in which a monocrystalline compound or crystal can be grown.

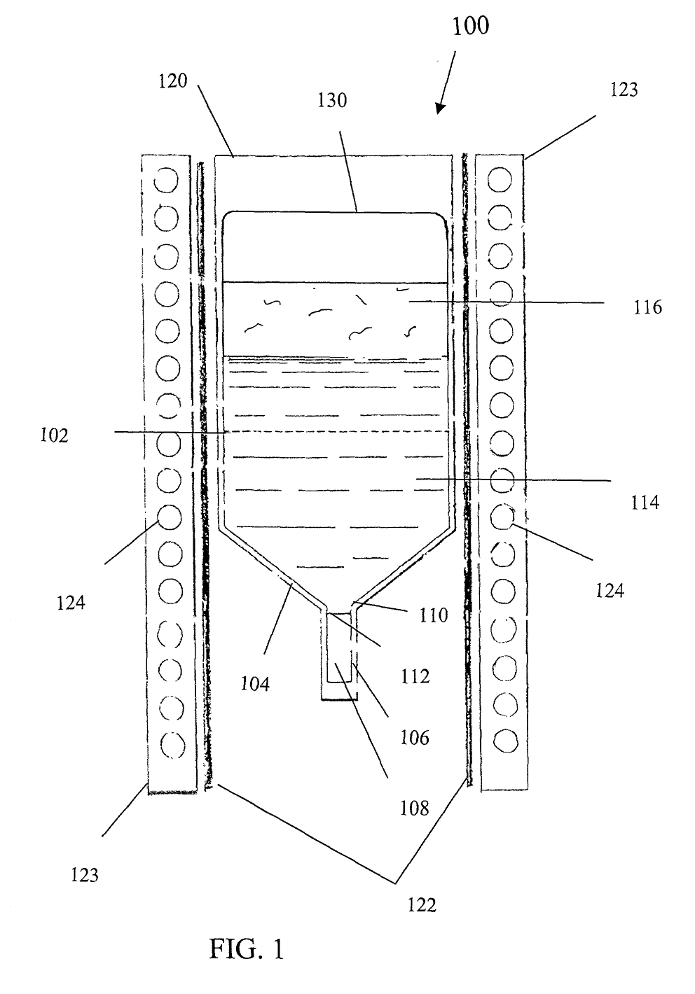

FIG. 1 shows an apparatus 100 for growing monocrystalline Group II-VI and III-V compounds constructed according to a first embodiment of the invention. The apparatus 100 includes a crucible 130 of generally cylindrical shape. The crucible 130 is made of pyrolytic boron nitride (PBN) The crucible 130 has a conical bottom 104 with a central region 106 that contains a solid seed crystal material 108 as shown in FIG. 1. The seed crystal 108 extends upward towards a top 110 of the seed well 106 to present a seed crystal surface 112. This surface 112 provides a crystalline format for growth of a monocrystalline compound 114 in the crucible. The monocrystalline compound 114 grown in accordance with the present invention is preferably a Group III-V, II-VI or related compound such as GaAs, GaP, GaSb, InAS, InP, InSb, AlAs, AlP, AlSb, GaAlAs, CdS, CdSe, CdTe, PbSe, PbTe, PbSnTe, ZnO, ZnS, ZnSe or ZnTe.

Large solid chunks of polycrystalline compound are initially loaded into crucible 130. Solid pieces of an oxide of boron such as B₂O₃ are loaded with the larger solid chunks of polycrystalline compound into the crucible 130. Suitable dopant materials such as carbon may then be introduced directly into the crucible 130 or other parts of a sealed ampoule 120 to produce doped monocrystalline compounds 114 in accordance with techniques familiar to those skilled in the art.

In FIG. 1, the loaded crucible 130 is placed in an ampoule 120 preferably made of quartz. The ampoule 120 is preferably sealed with a quartz cap after the crucible 130 is placed in the ampoule 120. The sealed ampoule 120, containing the crucible 130, is then inserted into a liner 122 in a heating unit 123 having heating elements 124. This liner 122 is preferably shaped as a cylindrical tube which is open at both ends. The liner 122 surrounds the ampoule 120 which encloses the charge 108 and crucible 130. The relative spacing between the liner 122 and the ampoule 120 is preferably 0.1 mm or greater. The wall thickness of both the liner 122 and the ampoule 120 is greater than 1 mm and preferably in the range of 2-8 mm. The crucible 130, ampoule 120, and liner 122 have longitudinal axes oriented substantially vertically as is accustomed in a VGF or LEC system.

After assembly, the apparatus 100 is heated by heating elements 124 such that the solid chunks of raw material are melted. Applying varying power to the heating elements 124 forms a temperature gradient and a solid-liquid interface 102. Initially, all the raw material is a melt and the seed crystal 108 is the only solid. The solid-liquid interface is initially at the top surface 112 of the seed crystal 108. The temperature gradient is slowly moved up through the melt such that a monocrystal 114 grows from the seed crystal 108. The solid-liquid interface 102 gradually rises as more of the melt 116 solidifies and the monocrystal grows.

In FIG. 1, the liner 122 is preferably made of quartz. Quartz has a relatively low thermal conductivity, as shown in Table 1 below. Thus, by forming the liner 122 of a quartz material, the liner 122 provides excellent temperature uniformity to the charge during the melting of the raw materials, the formation of the monocrystalline compound or crystal 114, and the cooling of the crystal 114. As a result, the quartz liner 122 generates a controlled, gradual, uniform temperature gradient that enables crystal growth with minimal thermal stress. Because of the presence of liner 122, crystals 114 grown using apparatus 100 have reduced intrinsic stress and fewer crystallographic defects. Crystal growth yield is dramatically improved, and enhanced yield and performance of microelectronic devices made from these crystals 114 can also be measured.

By forming both the liner 122 and the ampoule 120 of the same material, such as quartz, not only do the liner 122 and the ampoule 120 have substantially the same thermal conductivity. The liner 122 and ampoule 120 also have substantially the same thermal expansion coefficients. Thus, physical stress between the liner 122 and the ampoule 120 is averted. The propensity of the ampoule 120 to crack is reduced during crystal growth, and fewer crystals are lost. Crystal production yield is improved, and the liner 122 can be used in more growth cycles than diffusers made of other materials.

Table 1 provides a comparison between coefficients of thermal expansion and thermal conductivity for the materials quartz, silicon carbide, and mullite.

TABLE 1
Comparison between Coefficients of thermal
expansion and thermal conductivity

| | Coefficient of thermal | Thermal conductivity |
|---|---|---|
| Material | expansion cm/cm ° C. | g cal/(sec) (cm⁻²) (° C./cm) |
| Quartz | 5.5 × 10⁻⁷ | .0033 |
| Silicon Carbide | 3.8 − 4.8 × 10⁻⁶ | 1.19 − 3.26 |
| Mullite | 2.3 − 5.0 × 10⁻⁶ | .09 − .143 |

Other properties make quartz an appropriate material for liner 122 in crystal growth apparatus 100. Quartz does not react with most acids, metals, chloride, and bromide at ordinary temperatures. Quartz has good mechanical and electrical properties and is elastic. For these reasons, a quartz liner 122 is well suited for an apparatus 100 for growing monocrystalline Group II-VI and III-V compounds. The liner can be reused for several crystal growth processes.

In FIG. 1, the heating unit 123 is disposed about the ampoule 120. The liner 122 is disposed between the ampoule 120 and the heating unit 123. The heating unit 123 includes, for example, heating coils or other suitable heating elements 124 for controllably heating the liner 122, ampoule 120, and crucible 130. The heating unit 123 further includes a means for monitoring the temperature.

In FIG. 1, the crystal growth apparatus 100 is acted on in a sequence of control procedures well known in the art. The crucible 130 inside the ampoule 120 is heated, melted and cooled under controlled conditions. After the crucible 130 and ampoule 120 are cooled to room temperature, the ampoule 120 can be removed from the liner 122 and opened to reveal a single crystal ingot.

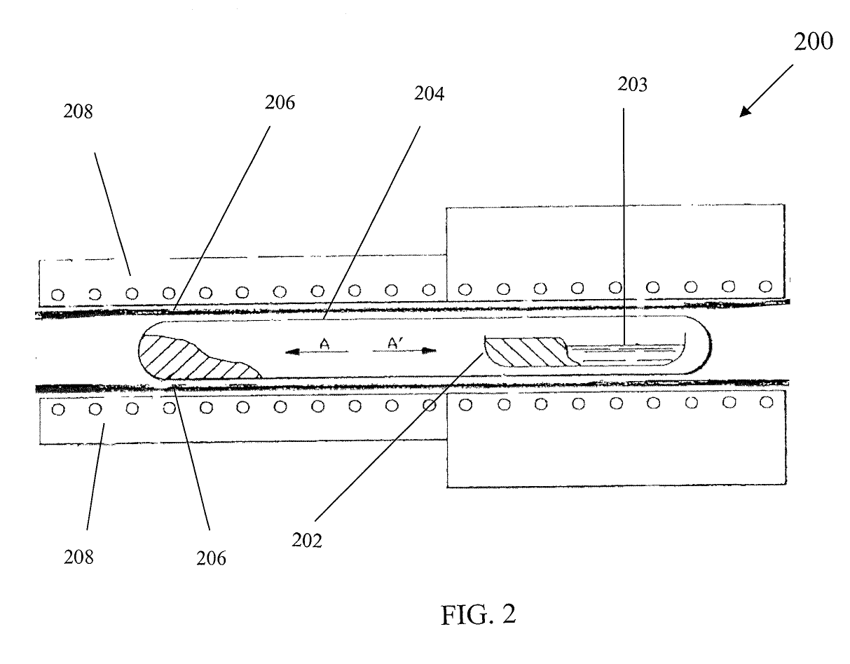

FIG. 2 shows an apparatus 200 for growing monocrystalline Group II-VI and III-V compounds, constructed according to a second embodiment of the invention. The apparatus 200 includes a boat 202 in which raw materials 203 are deposited. The boat 202 is contained in an ampoule 204. The ampoule 204 is preferably made of quartz. A liner 206 made of a quartz material is provided in apparatus 200. The liner 206 has the same tubular shape and properties as the liner 122 described above with reference to FIG. 1.

In FIG. 2, the liner 206 is disposed between the ampoule 204 and a heating unit 208 surrounding the ampoule 204. The liner 206 surrounds and encloses the ampoule 204. The boat 202, ampoule 204, and liner 206 have longitudinal axes oriented substantially horizontally as is accustomed in an HB or HGF system.

In FIG. 2, the apparatus 200 establishes a fixed temperature gradient that is horizontally oriented and encloses a movable deck. The boat 202 moves on the deck through the gradient under controlled conditions, and raw materials 203 within boat 202 are thus melted and converted to a monocrystalline compound. The liner 206 has substantially the same effect as liner 122 of the first embodiment described with reference to FIG. 1. That is, the liner 206 enables uniform heating and cooling and provides a uniform temperature gradient that can be carefully controlled and free from hot spots.

It should be emphasized that the above-described embodiments of the invention are merely possible examples of implementations set forth for a clear understanding of the principles of the invention. Variations and modifications may be made to the above-described embodiments of the invention without departing from the spirit and principles of the invention. All such modifications and variations are intended to be included herein within the scope of the invention and protected by the following claims.

What is claimed is:

1. An apparatus for growing monocrystalline Group II-VI and III-V compounds, the apparatus comprising:
a crucible;
an ampoule containing the crucible, the ampoule having a thermal expansion coefficient;
a heating unit disposed about the ampoule; and
a liner disposed between the ampoule and the heating unit and surrounding the ampoule, the liner composed of a material having a thermal expansion coefficient substantially matching the thermal expansion coefficient of the ampoule.

2. An apparatus for growing monocrystalline Group II-VI and III-V compounds in accordance with claim 1, the material composing the liner having a thermal conductivity substantially matching a thermal conductivity of the ampoule.

3. An apparatus for growing monocrystalline Group II-VI and III-V compounds in accordance with claim 1, the material composing the liner being quartz.

4. An apparatus for growing monocrystalline Group II-VI and III-V compounds in accordance with claim 1, the ampoule being composed of quartz.

5. An apparatus for growing monocrystalline Group II-VI and III-V compounds in accordance with claim 1, the liner having a wall thickness greater than about 1 millimeter.

6. An apparatus for growing monocrystalline Group II-VI and III-V compounds in accordance with claim 1, the liner having a wall thickness between about 2 millimeters and 8 millimeters.

7. An apparatus for growing monocrystalline Group II-VI and III-V compounds, the apparatus comprising:
a boat having a longitudinal axis oriented substantially horizontally;
an ampoule containing the boat, the ampoule having a longitudinal axis oriented substantially horizontally, the ampoule having a thermal expansion coefficient;
a heating unit disposed about the ampoule; and
a liner disposed between the ampoule and the heating unit and surrounding the ampoule, the liner having a longitudinal axis oriented substantially horizontally, the liner composed of a material having a thermal expansion coefficient substantially matching the thermal expansion coefficient of the ampoule.

8. An apparatus for growing monocrystalline Group II-VI and III-V compounds in accordance with claim 7, the material composing the liner having a thermal conductivity substantially matching the thermal conductivity of the ampoule.

9. An apparatus for growing monocrystalline Group II-VI and III-V compounds in accordance with claim 7, the material composing the liner being quartz.

10. An apparatus for growing monocrystalline Group II-VI and III-V compounds in accordance with claim 7, the ampoule being composed of quartz.

11. An apparatus for growing monocrystalline Group II-VI and III-V compounds in accordance with claim 7, the liner having a wall thickness greater than about 1 millimeter.

12. An apparatus for growing monocrystalline Group II-VI and III-V compounds in accordance with claim 7, the liner having a wall thickness between about 2 millimeters and 8 millimeters.

13. An apparatus for growing monocrystalline Group II-VI and III-V compounds, the apparatus comprising:
a crucible having a longitudinal axis oriented substantially vertically;
an ampoule containing the crucible, the ampoule having a longitudinal axis oriented substantially vertically;
a heating unit disposed about the ampoule; and
a liner disposed between the ampoule and the heating unit and surrounding the ampoule, the liner having a longitudinal axis oriented substantially vertically, the liner being composed of quartz.

14. An apparatus for growing monocrystalline Group II-VI and III-V compounds in accordance with claim 13, the ampoule being composed of quartz.

15. An apparatus for growing monocrystalline Group II-VI and III-V compounds in accordance with claim 13, the liner having a wall thickness greater than about 1 millimeter.

16. An apparatus for growing monocrystalline Group II-VI and III-V compounds in accordance with claim 13, the liner having a wall thickness between about 2 millimeters and 8 millimeters.

17. A liner for use in an apparatus for growing monocrystalline Group II-VI and III-V compounds, the apparatus including a crucible, an ampoule containing the crucible, and a heating unit disposed about the ampoule, the liner to be disposed between the ampoule and the heating unit, the liner being composed of quartz.
